(19) United States
(12) Patent Application Publication
(10) Pub. No.: US 2002/0050858 A1
(43) Pub. Date: May 2, 2002

(54) Preamplifier circuit

(76) Inventor: Akira Arimizu, Kagoshima (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 09/927,534

(22) Filed: Aug. 13, 2001

(30) Foreign Application Priority Data
Aug. 15, 2000 (JP) P2000-246473

(51) Int. Cl. H03F 3/00; H03F 1/00

(52) U.S. Cl. 330/185

(57) ABSTRACT

The present invention relates to a preamplifier for computer display for transmitting an analog video signal as a result of converting a digital video signal outputted from a computer by a video D/A converter circuit of a digital signal processing IC to a display, wherein an input characteristic of the preamplifier is current input to match a characteristic of current output of the video D/A converter circuit.

### BACKGROUND OF THE INVENTION

The present invention relates to a preamplifier circuit, and particularly to a preamplifier circuit for color display.

FIG. 5 is a block diagram of a common display system for computer display. In FIG. 5, reference numeral 2 denotes a preamplifier; reference numeral 3 denotes a main amplifier; and reference numeral 4 designates a CRT. FIG. 6 is a block diagram of a display system expected hereafter in a case where a digital input signal is supplied from a computer proper to the display. In FIG. 6, reference numeral 1 denotes a digital signal processing circuit; reference numeral 2 denotes a preamplifier; reference numeral 3 denotes a main amplifier; reference numeral 4 designates a CRT; reference numeral 5 designates a current-voltage converter circuit; and reference numeral 6 designates a buffer amplifier.

As shown in FIG. 5, a current computer display receives an analog signal from a computer. The preamplifier 2 mixes the analog signal with an OSD (On Screen Display) signal and a blanking signal. After contrast and brightness are adjusted, the main amplifier 3 amplifies the mixed signal to an amplitude of a few tens of Vpp, and then sends the signal to the CRT 4.

With the recent spreading use of an LCD display, there are some cases where a digital signal is transmitted between the computer and the display as it is without being converted into an analog signal, as shown in FIG. 6. By transmitting a digital signal between the computer and the display, the display can independently perform various image processing, and also image degradation in a signal transmission path can be prevented. Thus, the use of such transmission of a digital signal is expected to increase in the future.

FIG. 7 shows details of circuit configuration between the digital signal processing circuit 1 and the preamplifier 2 in the display system for computer display shown in the block diagram of FIG. 6. In FIG. 7, reference numeral 1 denotes the digital signal processing IC; reference numeral 2 denotes the preamplifier; reference numeral 5 denotes a load resistance as the current-voltage converter circuit; reference numeral 6 is the buffer amplifier; reference numeral 7 is wiring capacitance of a substrate pattern; reference numeral 11 is a reference current source; reference numeral 12 designates a video DAC (Digital to Analog Converter); reference numeral 13 designates a reference resistance; and reference numeral 14 designates a direct-current power supply. While FIG. 7 shows circuits for only the R signal of the R, G, and B signals, the same circuits are provided for the G signal and the B signal.

However, output of the current digital signal processing IC is generally produced by the current output type wide-band video DAC 12 as shown in FIG. 7. On the other hand, the preamplifier 2 generally accepts voltage signal input. Thus, specifications for input/output of the digital signal processing IC and the preamplifier are different from each other. Therefore, an output signal current of the digital signal processing IC 1 is converted into a voltage by the load resistance 5, and then the voltage is inputted to the preamplifier 2.

In this case, since the current-voltage conversion is performed by the load resistance 5 external to the IC, stray capacitance becomes larger and frequency characteristics tend to be degraded more than when the current-voltage conversion is performed within the IC. Also, wiring resistance and wiring capacitance of a substrate wiring pattern after the voltage conversion degrade frequency characteristics in a transmission system (since a signal is inputted to the preamplifier 2 via the wiring capacitance 7 of the substrate pattern and a clamp capacitor, the preamplifier 2 side appears to have high impedance when viewed from the digital signal processing IC 1). Because of the high signal band, it is necessary to provide the buffer amplifier 6 between the load resistance 5 and the preamplifier 2 in order to control the degradation in frequency characteristics caused by the substrate pattern wiring capacitance.

As described above, the current output of the digital signal processing IC is converted into a voltage signal by using the external load resistance, and then the voltage signal is inputted to the conventional preamplifier for computer display. Thus, there are problems of susceptibility to stray capacitance and degradation in frequency characteristics. In order to avoid this, it is necessary to provide the buffer amplifier between the load resistance and the preamplifier.

### SUMMARY OF THE INVENTION

It is an object of the present invention to realize a preamplifier circuit for computer display that makes it possible to obtain excellent frequency characteristics without adding extra components to the digital signal processing IC and the preamplifier by a relatively simple method of matching specifications for the output of the digital signal processing IC and the signal input of the preamplifier to each other.

In order to achieve the above object, according to the present invention, there is provided a preamplifier circuit for computer display for transmitting an analog video signal as a result of converting a digital video signal outputted from a computer by a D/A converter circuit to a display, wherein an input characteristic of the preamplifier circuit is current input to match a characteristic of current output of the D/A converter circuit.

Thus, it is possible to realize a preamplifier circuit for computer display that makes it possible to obtain excellent frequency characteristics with a relatively small number of components and with reduced susceptibility to stray capacitance.

### BRIEF DESCRIPTION OF THE DRAWINGS

FIG. 1 is a block diagram of a display system for computer display using a preamplifier circuit according to the present invention;

FIG. 2 is a detail diagram of configuration of a preamplifier circuit according to an embodiment of the present invention and a digital signal processing circuit in the preceding stage;

FIG. 3 is a detail diagram of configuration of a preamplifier circuit according to another embodiment of the present invention and a digital signal processing circuit in the preceding stage;

FIG. 4 is a circuit diagram of a current conversion circuit employing a transconductance amplifier used in a preamplifier circuit according to the present invention;

FIG. 5 is a block diagram of a conventional common display system for computer display;

FIG. 6 is a block diagram of a display system for computer display in a case where a digital output signal is supplied from a computer proper; and

FIG. 7 is a detail diagram of circuit configuration between a digital signal processing circuit and a preamplifier in the configuration of FIG. 6.

### DETAILED DESCRIPTION OF THE INVENTION

A preamplifier circuit according to the present invention will hereinafter be described in detail with reference to the accompanying drawings.

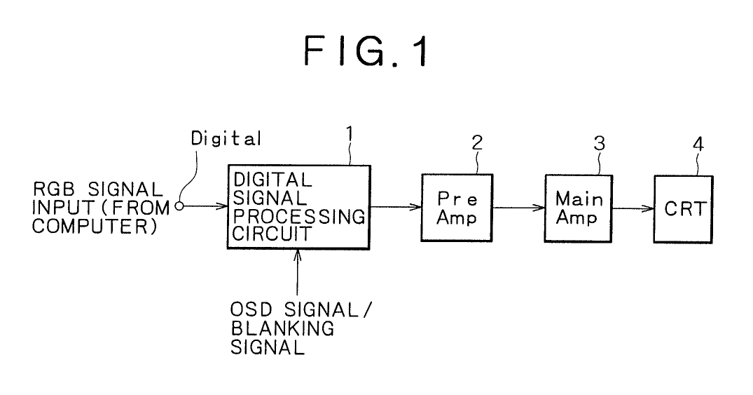

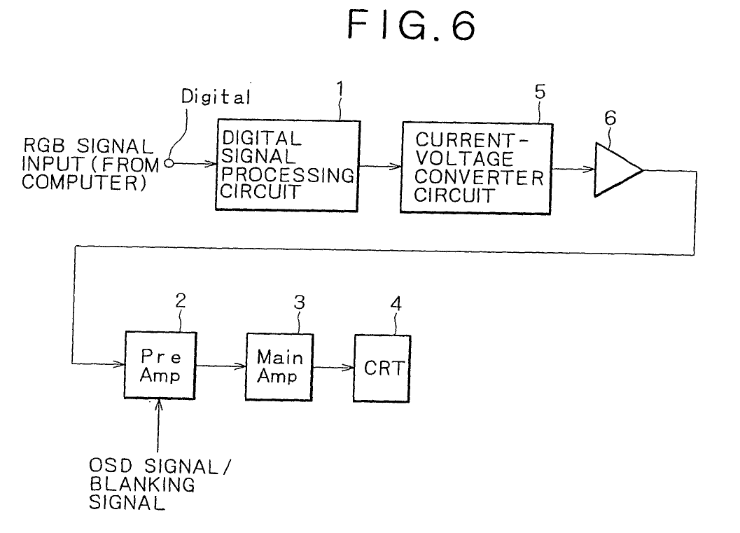

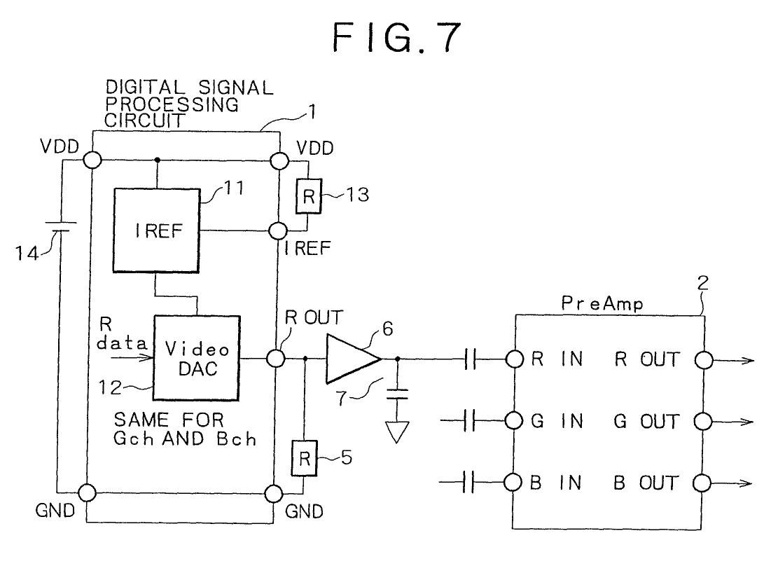

FIG. 1 is a block diagram of a display system for computer display using the preamplifier circuit according to the present invention. In FIG. 1, reference numeral 1 denotes a digital signal processing circuit; reference numeral 2 denotes a preamplifier; reference numeral 3 denotes a main amplifier; and reference numeral 4 designates a CRT. The display system has a system configuration in which the current-voltage converter circuit and the buffer amplifier in FIG. 6 are removed by matching signal input/output specifications of the digital signal processing IC 1 and the preamplifier circuit 2 to each other.

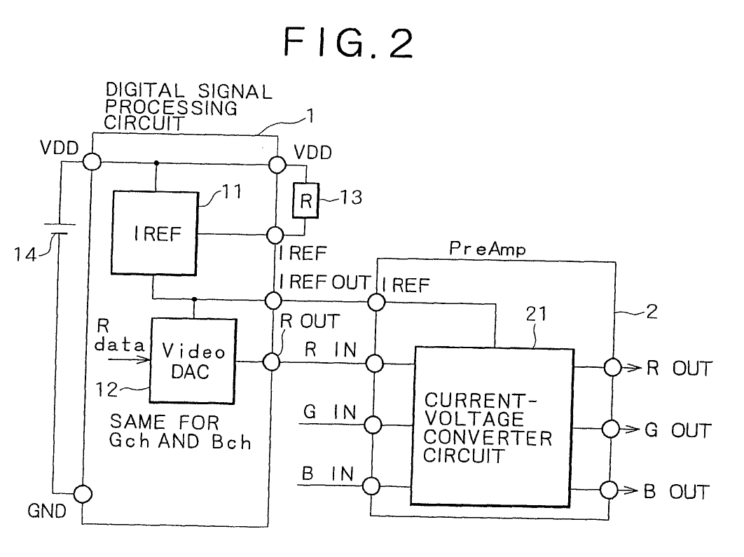

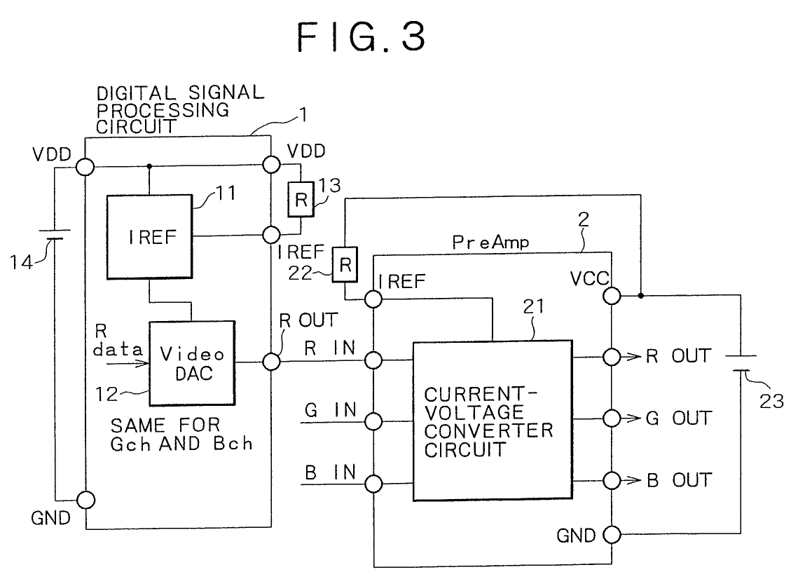

FIG. 2 and FIG. 3 show details of the configuration between the digital signal processing circuit 1 and the preamplifier 2 in the display system for computer display shown in the block diagram of FIG. 1. While FIG. 2 and FIG. 3 show circuits for only the R signal of the R, G, and B signals, the same circuits are provided for the G signal and the B signal. In FIG. 2 and FIG. 3, reference numeral 1 denotes the digital signal processing IC; reference numeral 2 denotes the preamplifier; reference numeral 11 denotes a reference current source; reference numeral 12 designates a video DAC; reference numeral 13 designates a reference resistance; reference numeral 14 designates a direct-current power supply; reference numeral 21 denotes a current conversion circuit; reference numeral 22 denotes a reference resistance; and reference numeral 23 denotes a direct-current power supply.

A problem in realizing current input of the preamplifier 2 is to prevent effects of variations and temperature characteristics of an internal resistance used to convert a signal current into a voltage in the preamplifier from being produced on output signal amplitude.

The present invention solves this problem by supplying a reference current (IREF) from the digital signal processing IC 1 to the preamplifier 2 as shown in FIG. 2 or generating a reference current (IREF) within the preamplifier 2 using the external reference resistance 22 of the preamplifier 2 as shown in FIG. 3, and then providing the current conversion circuit 21 formed by using the reference current (IREF) and the internal resistance within the preamplifier 2.

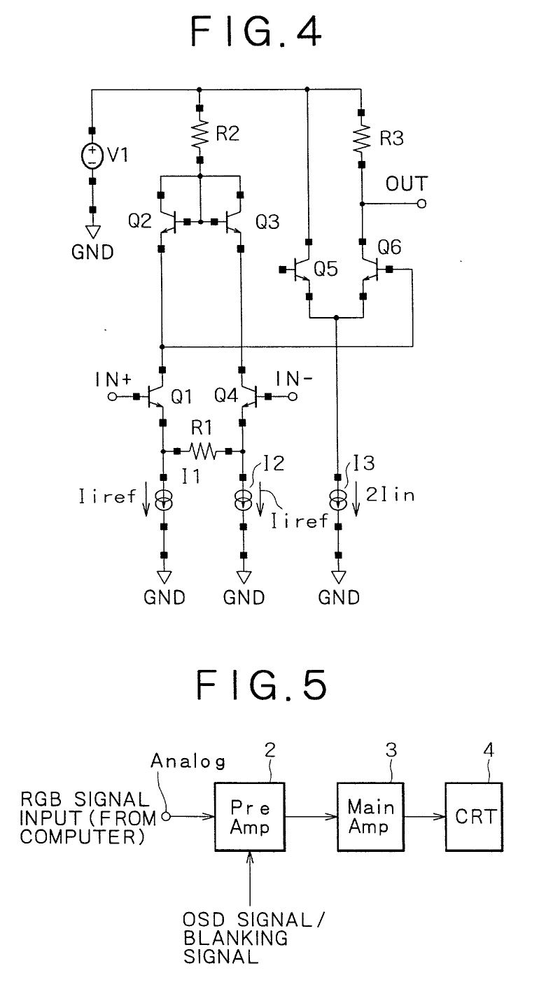

The conversion circuit 21 can be realized by a transconductance amplifier employing pairs of transistors, as shown in FIG. 4, whose characteristics coincide with each other and using change in transconductance of the transistors.

In FIG. 4, Iiref is a reference current (IREF) that is dependent on external resistance (having variations and temperature characteristics much less significant than those of internal resistance of the IC), whereas Iin is a current that is dependent on the internal resistance of the IC. A video signal inputted to an IN+/IN− terminal is passed through the transconductance amplifier and then outputted from an OUT terminal. The video signal inputted to the IN+/IN− terminal has been subjected to current-voltage conversion by the internal resistance of the preamplifier IC before inputted to the circuit of FIG. 4 and thus has become a voltage signal. However, since input impedance of the transconductance amplifier is low, the current-voltage conversion is also performed by the low resistance, and current input can be realized by lowering input resistance of the preamplifier 2.

Letting ΔVin be a differential voltage of the IN+ and IN− terminals, ΔV be a differential voltage between bases of a transistor Q5 and a transistor Q6, and ΔVout be a voltage variation of the OUT terminal in the circuit of FIG. 4,

ΔV=2re*{ΔVin/(R1+2re)} (1)

where re is emitter resistance of transistors Q1, Q2, Q3, and Q4, and re=Vt/Iiref (where Vt is thermal voltage of the transistors).

ΔVout=R3*{ΔV/(2re′)} (2)

where re′ is emitter resistance of the transistors Q5 and Q6, and re′=Vt/Iin.

The equation (1) is substituted into the equation (2).

$$Δ Vout = R3 * [ 2 re * \{ Δ Vin / ( R1 + 2 re ) \} / ( 2 {re}^{′} ) ] \\ = ( R3 / R1 ) * ( re / {re}^{′} ) * Δ Vin \\ = ( R3 / R1 ) * \{ ( Vt / Iiref ) / ( Vt / Iin ) \} * Δ Vin \\ = ( R3 / R1 ) * ( Iin / Iiref ) * Δ Vin \qquad ( 3 )$$

where since R1>>2re, R1+2re≈R1.

When Iiref and Iin are generated from a constant voltage Vref by the external resistance Rout and the internal resistance Rin of the IC, respectively, Iiref and Iin are expressed by the following equations.

Iiref=Vref/Rout (4)

Iin=Vref/Rin (5)

When letting A*Iiref be an input signal current from the digital signal processing IC (reference current is generated similarly to Iiref of the preamplifier), and performing voltage conversion by the resistance Rin within the preamplifier, Avin is expressed by the following equation.

ΔVin=A*Iiref*Rin (6)

From the equations (3) to (6),

$$\begin{matrix}Δ Vout = ( R3 / R1 ) * \{ ( Vref / Rin ) / ( Vref / Rout ) \} * A * Iiref * Rin \\ = ( R3 / R1 ) * \{ ( Vref / Rin ) / ( Vref / Rout ) \} * A * ( Vref / Rout ) * Rin \\ = ( R3 / R1 ) * A * Vref\end{matrix} \qquad ( 7 )$$

The resistance R1 and the resistance R3 are the internal resistances of the IC, and it can be considered from the equation (7) that although the resistance R1 and the resistance R3 have temperature characteristics and variations, the temperature characteristics and the variations of the resistance R1 and the resistance R3 cancel each other out. Therefore, it is understood that the effects of the temperature characteristics and the variations are not produced on output amplitude.

Thus, the present invention has the following effects.

1) By unifying specifications for the signal output of the digital signal processing IC and the signal input of the preamplifier, the output of the digital signal processing IC can be connected as it is to the preamplifier input. Therefore, an intermediate circuit is not required, whereby the number of parts can be reduced.

2) By making signal transmission between the digital signal processing IC and the preamplifier by current rather than voltage, degradation in frequency characteristics caused by stray capacitance, substrate pattern wiring capacitance and the like can be controlled. Therefore, it is possible to increase the degree of freedom of parts arrangement, wire routing and the like in substrate design.

3) By providing the current conversion circuit using the transconductance amplifier having a low input impedance in the preamplifier, it is possible to prevent effects of temperature characteristics and variations of the internal resistance of the IC from being produced on the output signal amplitude of the preamplifier. Thus, a circuit configuration suitable for higher IC integration can be provided.

While preferred embodiments of the present invention have been described using specific terms, such description is for illustrative purposes only, and it is to be understood that changes and variations may be made without departing from the spirit or scope of the following claims.

What is claimed is:

1. A preamplifier circuit for transmitting an analog video signal as a result of converting a digital video signal outputted from a computer by a D/A converter circuit to a display, wherein an input characteristic of said preamplifier circuit is current input to match a characteristic of current output of said D/A converter circuit.

2. A preamplifier circuit as claimed in claim 1, wherein a current conversion circuit using a transconductance amplifier is provided within said preamplifier circuit.
